(19) United States
(12) Patent Application Publication
(10) Pub. No.: US 2026/0140208 A1
(43) Pub. Date: May 21, 2026

(54) RADIO FREQUENCY COIL ASSEMBLY AND MAGNETIC RESONANCE IMAGING SYSTEM HAVING THE SAME

(71) Applicant: Shanghai United Imaging Healthcare Co., Ltd., Shanghai (CN)

(72) Inventors: Xiangming Hou, Shanghai (CN); Bing Wu, Shanghai (CN); Fuyi Fang, Shanghai (CN); Zidong Wei, Shanghai (CN); Jiankang Li, Shanghai (CN); Guobin Li, Shanghai (CN)

(21) Appl. No.: 19/389,112

(22) Filed: Nov. 14, 2025

(30) Foreign Application Priority Data
Nov. 15, 2024 (CN) 202411645032.7
Nov. 15, 2024 (CN) 202422805681.0

(51) Int. Cl. G01R 33/3415; G01R 33/30

(52) U.S. Cl. CPC G01R 33/3415; G01R 33/30

(57) ABSTRACT

The present application relates to a radio frequency coil assembly and a magnetic resonance imaging system. The radio frequency coil assembly includes a lower component, side components, and an upper component. At least one side component is detachably connected to opposite ends of the lower component; the upper component is rotatably connected to the lower component. The lower component, the side components, and the upper component cooperatively define an accommodating cavity with an opening. The side component is drivingly connected to the upper component. When the upper component is rotated relative to the lower component, the side component is driven by the upper component to move relative to the lower component, so as to adjust the volume size of the accommodating cavity.

### CROSS-REFERENCE TO RELATED APPLICATIONS

This application claims priority to Chinese patent application No. 202411645032.7, entitled “RADIO FREQUENCY COIL ASSEMBLY FOR MAGNETIC RESONANCE IMAGING SYSTEM AND MAGNETIC RESONANCE IMAGING SYSTEM” filed on Nov. 15, 2024, and Chinese patent application No. 202422805681.0, entitled “RADIO FREQUENCY COIL ASSEMBLY FOR MAGNETIC RESONANCE IMAGING SYSTEM AND MAGNETIC RESONANCE IMAGING SYSTEM” filed on Nov. 15, 2024, the contents of which are hereby incorporated by reference in its entirety.

### TECHNICAL FIELD

The present disclosure relates to the technical field of medical equipment, and in particular, to a radio frequency coil assembly and a magnetic resonance imaging system having the same.

### BACKGROUND

Magnetic resonance imaging devices are primarily used for examining patients through magnetic resonance tomography and have been widely applied in clinical diagnostic examinations and detections. Conventional magnetic resonance systems (also referred to as MR or MRT) typically include a plurality of different antennas (also referred to as coils) to transmit radio frequency pulses for magnetic resonance and/or acquire induced magnetic resonance signals. Magnetic resonance imaging devices usually include a relatively large coil (i.e., a whole-body coil, also referred to as a body coil or BC) and a plurality of smaller surface coils (also referred to as local coils). The body coil is typically permanently installed in the magnetic resonance system, while surface coils are used to capture detailed images of the specific regions or the organs near the body surface of the patient. For this purpose, surface coils are generally positioned over the patient's target regions to be examined.

The radio frequency coil assembly is designed to scan the head and neck region of a patient. Conventional radio frequency coil assemblies have a fixed internal space that cannot be adjusted to adapt to patients with varying anatomical dimensions.

### SUMMARY

Accordingly, it is necessary to provide a radio frequency coil assembly with an adjustable internal space and a magnetic resonance imaging system having the radio frequency coil assembly.

A radio frequency coil assembly for a magnetic resonance imaging system includes:
a lower component;
two side components detachably connected to opposite ends of the lower component, respectively; and
an upper component rotatably connected to the lower component and drivingly connected to at least one of the side components; wherein the lower component, the two side components, and the upper component are each provided with a coil unit therein, and the lower component, the two side components, and the upper component cooperatively define an accommodating cavity with an opening;
wherein when the upper component is rotated relative to the lower component, the at least one side component is driven by the upper component to move relative to the lower component, so as to adjust a volume size of the accommodating cavity.

In an embodiment, the upper component includes an insertion plug, the lower component includes an insertion portion, the insertion plug and the insertion portion are each provided with a connector, and the insertion plug is inserted into the insertion portion and electrically connected to the insertion portion via the connector.

In an embodiment, the radio frequency coil assembly further includes:
a pivot shaft connected to the upper component and capable of rotating relative to the lower component; and
a linkage assembly, wherein the side component is connected to the pivot shaft via the linkage assembly, so as to convert rotational motion of the upper component into translational motion of the two side components.

In an embodiment, the linkage assembly includes:
a drive gear fixedly connected to the pivot shaft;
a transmission shaft rotatably connected to the lower component, wherein two driven gears are provided at both ends of the transmission shaft, respectively;
a transmission rack movably connected to the lower component, wherein one driven gear is engaged with the drive gear, and another driven gear is engaged with the transmission rack; and
a sliding block fixedly connected to the side component, wherein the sliding block is drivingly connected to the transmission rack to drive the side component to move relative to the lower component, thereby increasing a distance between the two side components.

In an embodiment, the linkage assembly further includes:
a guide drive block fixedly connected to the transmission rack and including a guide slope, wherein the guide slope is inclined relative to an extending direction of the transmission rack;
wherein the sliding block abuts against the guide slope, when the transmission rack moves relative to the lower component in a first direction, the sliding block is driven by the guide slope to move in a second direction, and the first direction intersects the second direction.

In an embodiment, the lower component is provided with a guide rail extending in the second direction, a side of the sliding block is fixedly connected to the side component, and another side of the sliding block is slidably connected to the guide rail; when the transmission rack moves in the first direction, the sliding block moves along the guide rail under a force of the guide slope.

In an embodiment, an end surface of the guide drive block away from the transmission rack is a flat surface parallel to the transmission rack, and a surface of the sliding block abutting against the end surface of the guide drive block away from the transmission rack is also a flat surface.

In an embodiment, the linkage assembly further includes a sliding base fixedly connected to the sliding block,
wherein the side component is detachably connected to the sliding base, and the sliding base is provided with a connector electrically connected to the lower component.

In an embodiment, the linkage assembly further includes a first elastic member,
wherein one end of the first elastic member abuts against the sliding block, and another end of the first elastic member abuts against the lower component;
when the two side components move away from each other, the first elastic member is compressed and is configured to provide force for the two side components to move toward each other.

In an embodiment, an end of the sliding block away from the transmission rack is provided with a guide element, the lower component is provided with a guide rail extending in the second direction, and the first elastic member is provided within the guide element and abuts against a positioning protrusion on the guide rail.

In an embodiment, the radio frequency coil assembly further includes a locking assembly, wherein the two side components are detachably connected to the lower component via the locking assembly, and when the side components move to a predetermined position, the locking assembly is capable of locking the two side components relative to the lower component.

In an embodiment, the locking assembly includes:
a sleeve fixedly connected to the lower component;
a locking element rotatably connected to the side component, wherein the locking element is inserted into the sleeve; and
a position adjusting element fixedly connected to the locking element;
wherein the position adjusting element is capable of driving the locking element to rotate relative to the sleeve, thereby fixing the locking element to the sleeve.

In an embodiment, the position adjusting element includes a protrusion portion, and rotating the position adjusting element causes the protrusion portion to abut against the lower component, thereby locking the side component relative to the lower component.

In an embodiment, an end of the locking element away from the position adjusting element is provided with a limit groove, an inner peripheral surface of the sleeve is provided with a limit protrusion, and the limit protrusion cooperates with the limit groove to restrict the locking element from disengaging from the sleeve.

In an embodiment, the limit groove includes a helical segment and a transverse segment that are in communication with each other, an extending direction of the transverse segment is perpendicular to an axis of the locking element, and the limit protrusion enters the transverse segment from the helical segment.

In an embodiment, an outer peripheral surface of the locking element is further provided with an anti-rotation protrusion block, an end surface of the anti-rotation protrusion block towards the position adjusting element is provided with a toothed anti-rotation protrusion. The locking assembly further includes an anti-rotation pressure block, the anti-rotation pressure block is movably connected to the side component and is movably sleeved on the locking element. An end surface of the anti-rotation pressure block towards the anti-rotation protrusion is provided with an anti-rotation recess, and the anti-rotation protrusion and the anti-rotation recess cooperate with each other to restrict rotation of the locking element.

In an embodiment, the locking assembly further includes a second elastic element, the second elastic element is sleeved on the locking element, two ends of the second elastic element respectively abut against the anti-rotation pressure block and the position adjusting element to provide preload for the cooperation between the anti-rotation pressure block and the anti-rotation protrusion.

In an embodiment, the radio frequency coil assembly further includes a base and a tilt device, the lower component is connected to the base via the tilt device, and the tilt device is configured to adjust an angle between the lower component and the base.

A radio frequency coil assembly includes a lower component, an upper component, a left component, and a right component;
wherein the lower component, the upper component, the left component, and the right component are each provided with a coil unit therein;
wherein the upper component is rotatably connected to the lower component and is drivingly connected to the left component and the right component;
when the upper component rotates relative to the lower component from an open position to a closed position, the left component and the right component are driven by the upper component to move relative to the lower component toward a patient, thereby wrapping sides of a head of the patient.

In an embodiment, the left component and the right component are driven by the upper component to move relative to the lower component from the open position to a plurality of closed positions to adapt to patients with different head sizes.

In an embodiment, the left component and the right component rotate relative to the lower component along a longitudinal axis, or the left component and the right component translate horizontally relative to the lower component.

A magnetic resonance imaging system includes:
a patient couch; and
a radio frequency coil assembly provided on a surface of the patient couch, the radio frequency coil assembly including a lower component, an upper component, and at least one side component;
wherein each of the lower component, the upper component, and the at least one side component includes at least one coil unit;
wherein the upper component is rotatably connected to the lower component and is drivingly connected to the at least one side component;
when the upper component rotates relative to the lower component from an open position to a closed position, the at least one side component is driven by the upper component to move relative to the lower component horizontally from an open position to a plurality of closed positions to adapt to patients with different head sizes.

In an embodiment, when the upper component rotates relative to the lower component from the closed position to the open position, the at least one side component is driven by the upper component to move relative to the lower component horizontally from the closed position to the open position.

In an embodiment, sides of the lower component, the upper component, and the at least one side component towards the patients are matched with contours heads of the patients.

In an embodiment, the radio frequency coil assembly further comprises a base and a tilt device, the lower component is connected to the base through the tilt device, the base is connected to the patient couch, and the tilt device is configured to adjust an inclination angle of the radio frequency coil assembly relative to the patient couch.

In the aforementioned radio frequency coil assembly, by detachably connecting the two side components to the lower component, the radio frequency coil assembly can be configured with or without the side components according to different application requirements. Furthermore, the detachable connection of the side components to the lower component enables the coil units to be replaced individually, thereby facilitating maintenance. The upper component is rotatably connected to the lower component, allowing the upper component to open or close relative to the lower component via the rotation thereof, which facilitates the entry of the patient's head and neck into the accommodating cavity. Additionally, the side components are configured to be drivingly connected to the upper component, so that when the upper component rotates relative to the lower component, the side components can be driven by the upper component to move relative to the lower component, thereby adjusting the volume size of the accommodating cavity. This structural configuration enables the volume size of the accommodating cavity to be adjustable, so that the radio frequency coil assembly, when adapting to patients with different head sizes, can be better attached to the patient's head and neck by adjusting the volume size of the accommodating cavity, thereby improving the signal-to-noise ratio of the radio frequency coil assembly.

### BRIEF DESCRIPTION OF THE DRAWINGS

In order to illustrate the embodiments of the present disclosure more clearly, the drawings used in the embodiments or the conventional art will be described briefly. Apparently, the following described drawings are merely for the embodiments of the present disclosure, and other drawings can be derived by those of ordinary skill in the art without any creative effort.

FIG. 1 is a perspective view showing a radio frequency coil assembly with an upper component in a closed state according to an embodiment of the present application.

FIG. 2 is a perspective view showing a radio frequency coil assembly with an upper component in an open state according to an embodiment of the present application is in an open state.

FIG. 3 is a perspective view of an upper component of a radio frequency coil assembly according to an embodiment of the present application.

FIG. 4 is a perspective view showing a radio frequency coil assembly without an upper component according to an embodiment of the present application.

FIG. 5 is a perspective view of a linkage assembly mounted to the radio frequency coil assembly according to an embodiment of the present application.

FIG. 6 is a perspective view of a linkage assembly of a radio frequency coil assembly according to an embodiment of the present application.

FIG. 7 is a perspective view of a linkage assembly mounted to the radio frequency coil assembly, with side components removed, according to an embodiment of the present application;

FIG. 8 is a perspective view showing cooperation between a transmission rack and a sliding block in a linkage assembly of a radio frequency coil assembly according to an embodiment of the present application.

FIG. 9 is an exploded view of a locking assembly of a radio frequency coil assembly according to an embodiment of the present application.

FIG. 10 is a cross-sectional view of a locking assembly of a radio frequency coil assembly according to an embodiment of the present application.

FIG. 11 is a perspective view of a position adjusting element of a locking assembly of a radio frequency coil assembly according to an embodiment of the present application.

FIG. 12 is a perspective view of a position adjusting element of a locking assembly mounted on a side component, in a radio frequency coil assembly according to an embodiment of the present application.

FIG. 13 is a perspective view of a radio frequency coil assembly rotated at a certain inclination angle with an upper component in an open state according to an embodiment of the present application.

FIG. 14 is a perspective view of a radio frequency coil assembly from a rear perspective according to an embodiment of the present application.

FIG. 15 is a perspective view of a radio frequency coil assembly rotated at a certain inclination angle with an upper component in a closed state according to an embodiment of the present application.

FIG. 16 is a perspective view of a radio frequency coil assembly with a right side component removed according to an embodiment of the present application.

FIG. 17 is a perspective view of a radio frequency coil assembly with a right side component removed and an upper component in an open state according to an embodiment of the present application.

FIG. 18 is a perspective view of a radio frequency coil assembly with left and right side components removed according to an embodiment of the present application.

FIG. 19 is a perspective view of a tilt device of a radio frequency coil assembly according to an embodiment of the present application.

FIG. 20 is a perspective view of a radio frequency coil assembly installed on a patient couch according to an embodiment of the present application.

FIG. 21 is a perspective view of a radio frequency coil assembly installed on a patient couch, with an upper component in an open state, according to an embodiment of the present application.

FIG. 22 is a perspective view of a radio frequency coil assembly installed on a patient couch, with an upper component removed, according to an embodiment of the present application.

FIG. 23 is a perspective view of a radio frequency coil assembly installed on a patient couch, with left and right side components removed, according to an embodiment of the present application.

FIG. 24 is a perspective view of a radio frequency coil assembly installed on a patient couch, with an upper component and a right side component that are removed, according to an embodiment of the present application.

FIG. 25 is a perspective view of a radio frequency coil assembly installed on a patient couch, with a right side component removed and an upper component opened, according to an embodiment of the present application.

FIG. 26 is a perspective view of a radio frequency coil assembly installed on a patient couch, with the radio frequency coil assembly unit rotated at a certain inclination angle, left and right side components removed, and an upper component opened, according to an embodiment of the present application.

FIG. 27 is a perspective view of a radio frequency coil assembly installed on a patient couch, with the radio frequency coil assembly unit rotated at a certain inclination angle and an upper component removed, according to an embodiment of the present application.

FIG. 28 is a perspective view of a radio frequency coil assembly installed on a patient couch, with the radio frequency coil assembly unit rotated at a certain inclination angle, with both an upper component removed and left and right side components removed, according to an embodiment of the present application.

FIG. 29 illustrates a usage scenario of the radio frequency coil assembly at a lateral position according to an embodiment of the present application.

FIG. 30 illustrates a usage scenario of radio frequency coil assembly at a supine position according to an embodiment of the present application.

FIG. 31 is a perspective view showing a connection of a coil unit included in an upper component of a radio frequency coil assembly to a lower component according to an embodiment of the present application.

FIG. 32 is a perspective view showing a connection of a coil unit included in a side component of a radio frequency coil assembly to a lower component according to an embodiment of the present application.

### REFERENCE SIGNS

lower component: 100; insertion portion: 110; guide rail: 120; side component: 200; upper component: 300; insertion plug: 310; base: 400; pivot shaft: 500; linkage assembly: 600; drive gear: 610; transmission shaft: 620; transmission rack: 630; sliding block: 640; guide drive block: 650; guide slope: 651; sliding base: 660; driven gear: 670; protective sleeve: 680; locking assembly: 700; sleeve: 710; limit protrusion: 711; locking element: 720; limit groove: 721; helical segment: 7211; transverse segment: 7212; anti-rotation protrusion block: 722; anti-rotation protrusion: 7221; position adjusting element: 730; protrusion portion: 731; anti-rotation pressure block: 740; anti-rotation recess: 741; second elastic element: 750; tilt device: 800; gear assembly: 810; first bevel gear: 811; first transmission rod: 812; second transmission rod: 813; second bevel gear: 814; third bevel gear: 815; worm shaft: 820; connecting rod: 830; worm wheel: 840; handle: 850; pressing assembly: 860; accommodating cavity: 910; connector: 920; patient couch: 930; patient: 940; coil unit: 950; connection cable: 960.

### DETAILED DESCRIPTION

The embodiments of the present application will be described in detail with reference to the accompanying drawings in order to make the objects, features, and advantages of the present application more apparent and understandable. Many specific details are disclosed in the following description to facilitate a comprehensive understanding of the present application. However, it should be noted that the present application can be implemented in various ways different from those described herein, and those skilled in the art may make similar improvements without departing from the concept of the present application. Therefore, the present application is not limited to the specific embodiments disclosed below.

In the description of the present application, the orientation or position relationships indicated by the terms “central”, “longitudinal”, “transverse”, “length”, “width”, “thickness”, “upper”, “lower”, “front”, “back”, “left”, “right”, “vertical”, “horizontal”, “top”, “bottom”, “inner”, “outer”, “clockwise”, “counterclockwise”, “axial”, “radial”, “circumferential”, and the like are based on the orientation or position relationships shown in the accompanying drawings and are intended to facilitate the description of the present application and simplify the description only, rather than indicating or implying that the apparatus or element referred to must have a particular orientation or be constructed and operated in a particular orientation, and therefore are not to be interpreted as limiting the present application.

In addition, the terms “first” and “second” are used for descriptive purposes only, and cannot be construed as indicating or implying a relative importance, or implicitly specifying the number of the indicated technical features. Thus, the quantity of the feature defined with “first” or “second” may explicitly or implicitly be at least one. In the description of the present application, “a plurality of” means at least two, such as two, three, unless otherwise defined explicitly and specifically.

In the present application, unless otherwise specified and defined explicitly, the terms “install”, “connect”, “join”, and “fix” should be interpreted in a broad sense. For example, unless otherwise defined explicitly, they may refer to a fixed connection, a detachable connection, or an integral connection, may refer to a mechanical connection or an electrical connection, and may refer to a direct connection, an indirect connection via an intermediate medium, an internal communication between two elements, or interaction between two elements. The specific meanings of these terms in the present application can be understood based on specific circumstances by those of ordinary skills in the art.

In the present application, unless otherwise specified and defined explicitly, a first feature, when expressed as being “on” or “under” a second feature, may be in direct contact with the second feature or in indirect contact with the second feature via an intermediate medium. Furthermore, a first feature, when expressed as being “over”, “above” or “on top of” a second feature, may be located right above or obliquely above the second feature, or only located at a level higher than that of the second feature. A first feature, when expressed as being “below”, “underneath” or “under” a second feature, may be located right below or obliquely below the second feature, or only located at a level lower than that of the second feature.

It should be noted that when an element is referred to as being “fixed to” or “arranged on” another element, it may be directly provided on the other element or an intermediate element may exist. When an element is considered to be “connected to” another element, it may be directly connected to the other element or an intermediate element may co-exist. The terms “vertical”, “horizontal”, “upper”, “lower”, “left”, “right” and similar expressions used herein are only for illustrative purposes and are not intended to represent the only implementations.

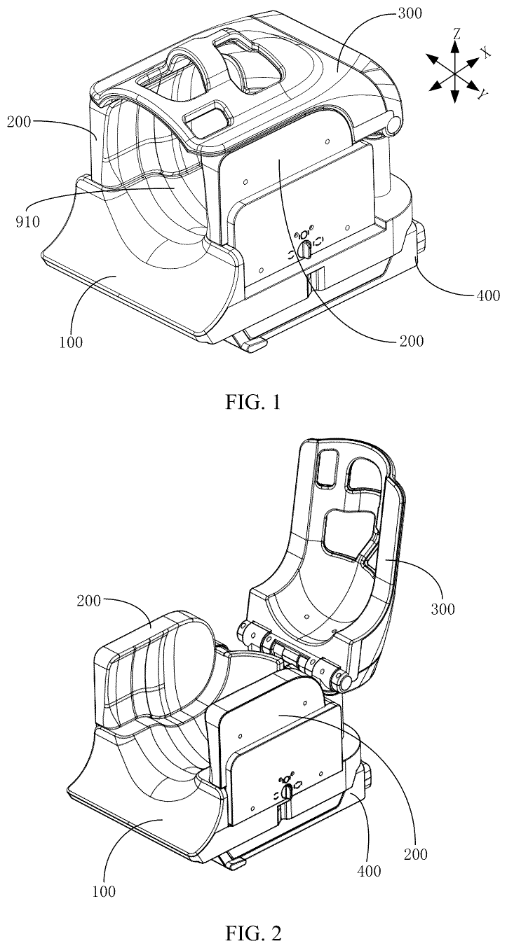

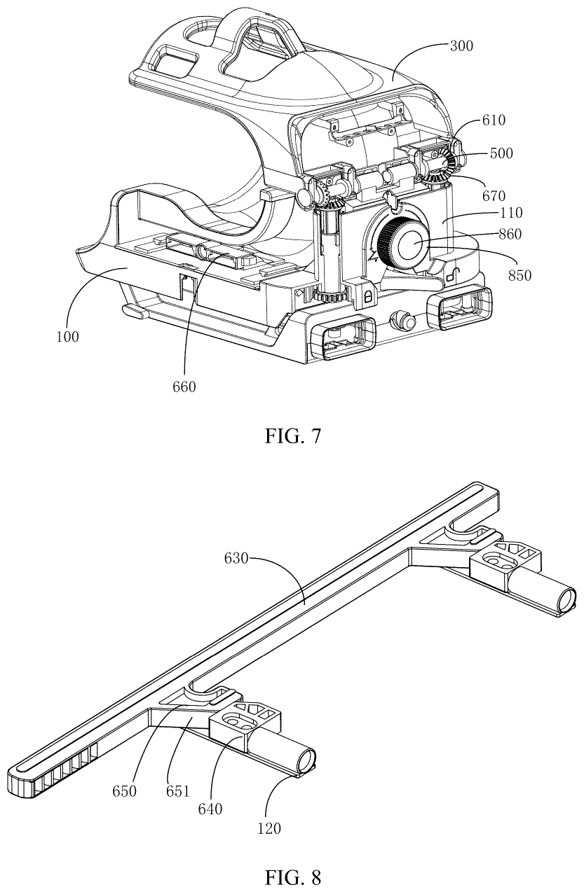

Referring to FIGS. 1 to 8, an embodiment of the present disclosure provides a radio frequency coil assembly for scanning a head and a neck of a patient 940. The radio frequency coil assembly includes a lower component 100, two side components 200, and an upper component 300. The lower component 100 is configured to abut against a posterior portion of a head of a patient. The two side components 200 are detachably connected to opposite ends of the lower component 100, respectively. The upper component 300 is configured to surround substantially a circumference of an anterior portion of the head of the patient. The upper component 300 is rotatably connected to the lower component 100 and is drivingly connected to at least one side component 200. The upper component 300, the two side components 200, and the lower component 100 can be connected electrically and cooperatively form a complete coil, or can each be individually provided with a coil unit. The lower component 100, the two side components 200, and the upper component 300 cooperatively define an accommodating cavity 910 with an opening. When the upper component 300 is rotated relative to the lower component 100, the at least one side component 200 is driven by the upper component 300 to move relative to the lower component 100, thereby adjusting a volume size of the accommodating cavity 910.

In the aforementioned radio frequency coil assembly, since the two side components 200 are detachably connected to the lower component 100, the side components 200 can be mounted or detached according to different application requirements. Furthermore, the detachable connection of the side components 200 to the lower component 100 enables the coil units to be replaced individually, thereby facilitating maintenance. The upper component 300 is rotatably connected to the lower component 100, such that the upper component 300 can rotate relative to the lower component 100 from an open position to a closed position, which facilitates the entry of the patient's head and neck into the accommodating cavity 910. Additionally, the side components 200 are drivingly connected to the upper component 300, so that when the upper component 300 rotates relative to the lower component 100, the side components 200 can be driven by the upper component 300 to move relative to the lower component 100. For example, the side components 200 may move towards the patient 940 to wrap the sides of the patient's head tightly, thereby adjusting the volume size of the accommodating cavity 910. This structural configuration allows the two side components 200 to move relative to the lower component 100 from an open position to a plurality of closed positions, so that when the radio frequency coil assembly is adapted to patients 940 with different head sizes, the two side components 200 can be better attached to the patient's head and neck by adjusting the volume size of the accommodating cavity 910, thereby improving the signal-to-noise ratio of the radio frequency coil assembly.

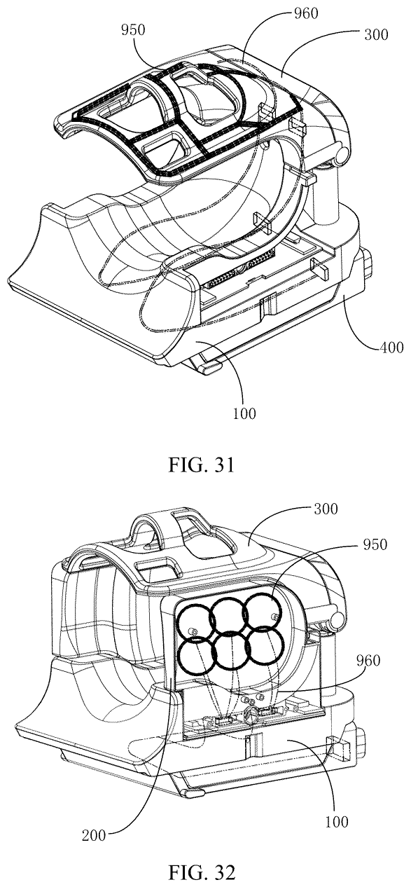

Specifically, as shown in FIGS. 31 and 32, the lower component 100, the side components 200, and the upper component 300 each include a housing and a coil unit 950 provided in the housing, and the coil unit 950 is configured to transmit a radio frequency field and receive detection signals. Since the coil units 950 are provided in the lower component 100, the side components 200, and the upper component 300, when the upper component 300 and the side components 200 are connected to the lower component 100, electrical connections between the coil units 950 can be achieved via connection cables 960.

In the embodiment, the sides of the lower component 100, the upper component 300, and the two side components 200 facing the patient 940 are complementary to a contour of the head of the patient 940. Specifically, an arc-shaped groove concaved downwardly is provided on the side of the housing of the lower component 100 towards the upper component 300 to adapt to the ergonomic structure, thereby improving the fit between the radio frequency coil assembly and the patient's head and neck during detection, and thus improving the signal-to-noise ratio.

For ease of understanding, the extending direction of the accommodating cavity 910 of the radio frequency coil assembly is referred to as a first direction X, which is the front-rear direction in FIG. 1. The first direction X is consistent with the extending direction of the human body during detection. The movement direction of the two side components 200 can be referred to as a second direction Y, which is the left-right direction in FIG. 1. The arrangement direction of the upper component 300 and the lower component 100 is referred to as a third direction Z, which is the up-down direction in FIG. 1.

In the embodiment, the functions such as the rotation of the upper component 300 and the movement of the side components 200 relative to the lower component 100 are achieved primarily through the mechanical structures on the housings of the side components 200, the lower component 100, and the upper component 300.

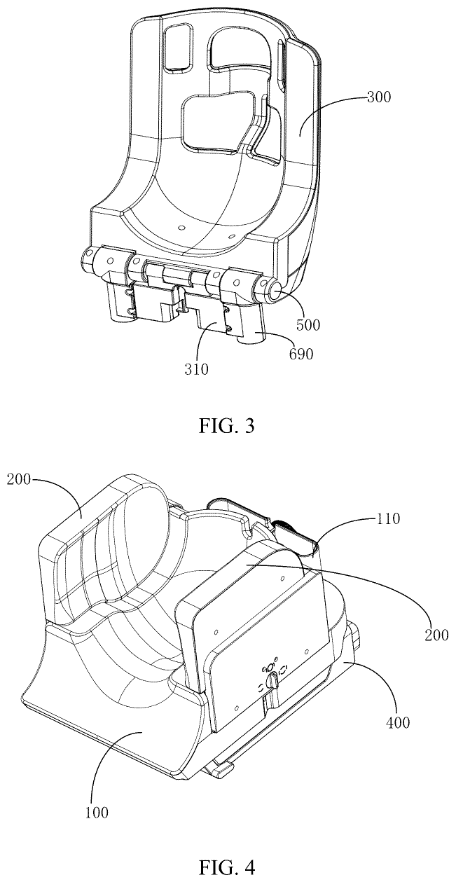

As shown in FIG. 3, in an embodiment, the radio frequency coil assembly further includes a pivot shaft 500. The pivot shaft 500 is connected to the upper component 300 and is capable of rotating relative to the lower component 100. The pivot shaft 500 extends along the second direction Y. By connecting the upper component 300 to the pivot shaft 500 and configuring the pivot shaft 500 to be capable of rotating relative to the lower component 100, the upper component 300 can be rotatable relative to the lower component 100.

As shown in FIGS. 3 and 4, in an embodiment, the upper component 300 includes an insertion plug 310, and the lower component 100 includes an insertion portion 110. Connectors 920 are provided within both the insertion plug 310 and the insertion portion 110. The insertion plug 310 extends along the third direction Z. The insertion portion 110 is provided with an insertion port. By inserting the insertion plug 310 into the insertion port of the insertion portion 110, the upper component 300 can be mechanically and electrically connected to the lower component 100. More specifically, engagement structures can be provided in the insertion plug 310 and the insertion portion 110 to achieve mutual limitation between the insertion plug 310 and the insertion portion 110.

As shown in FIGS. 3 to 5, in the embodiment, the insertion plug 310 is rotatably connected to the housing of the upper component 300 via the pivot shaft 500. After the insertion plug 310 is inserted into the insertion portion 110, the insertion plug 310 is fixed relative to the lower component 100. By rotating the upper component 300, the upper component 300 can be rotated relative to the lower component 100.

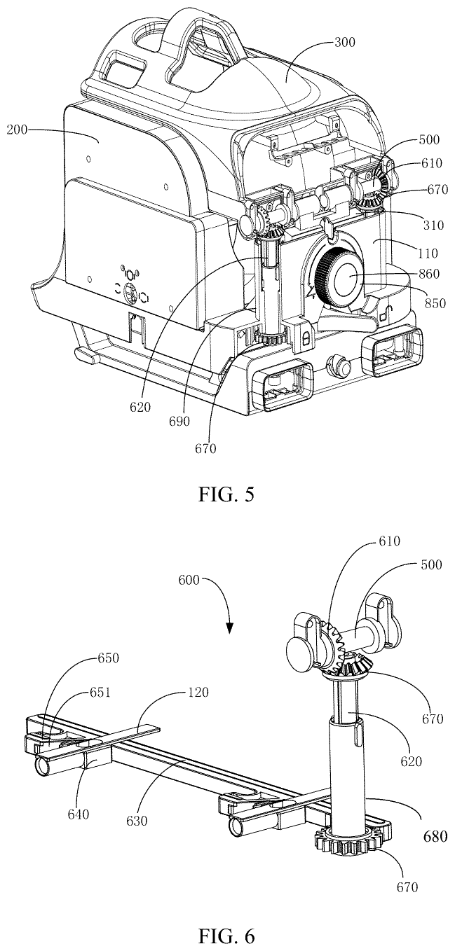

As shown in FIG. 5, in an embodiment, a pressing assembly 860 is provided on the lower component 100. The pressing assembly 860 can achieve the locking or unlocking of the upper component 300 relative to the lower component 100. When the upper component 300 is mounted onto the lower component 100, the pressing assembly 860 can lock the connection between them, thereby preventing disengagement of the upper component 300 from the lower component 100, and thus ensuring reliability during use in scenarios where the upper and lower components are connected. When the upper component 300 needs to be detached from the lower component 100, the locking between the upper component 300 and the lower component 100 can be unlocked by pressing the pressing assembly 860, thereby allowing the upper component 300 to be detached from the lower component 100.

As shown in FIG. 5 to FIG. 8, in an embodiment, the radio frequency coil assembly further includes a linkage assembly 600. The side component 200 is connected to the pivot shaft 500 via the linkage assembly 600, so as to convert rotational motion of the upper component 300 into translational motion of the two side components 200. When the upper component 300 is rotated relative to the lower component 100, since the linkage assembly 600 is connected to the pivot shaft 500, the linkage assembly 600 is drivingly connected to the upper component 300, such that the side component 200 can be driven by the linkage assembly 600 to move relative to the lower component 100.

Specifically, when rotating the upper component 300 to open the upper component 300 relative to the lower component 100, the two side components 200 are driven by the linkage assembly 600 to move away from each other, causing the distance between the two side components 200 to be increased, thereby enlarging the volume size of the accommodating cavity 910 of the radio frequency coil assembly, thus facilitating the head and neck of patients 940 with different head sizes to enter the accommodating cavity 910.

As shown in FIG. 5 to FIG. 8, in an embodiment, the linkage assembly 600 includes a drive gear 610, a transmission shaft 620, a transmission rack 630, and a sliding block 640. The drive gear 610 is fixedly connected to the pivot shaft 500. An end of the transmission shaft 620 is provided with a driven gear 670 that is engaged with the drive gear 610, and the other end of the transmission shaft 620 is provided with another driven gear 670 that is engaged with the transmission rack 630. The transmission shaft 620 is rotatably connected to the lower component 100. The transmission rack 630 is slidably connected to the lower component 100, and the transmission rack 630 is engaged with the driven gear 670. The sliding block 640 is fixedly connected to the side component 200, and the sliding block 640 is drivingly connected to the transmission rack 630 to drive the side component 200 to move relative to the lower component 100, thereby increasing or decreasing the distance between the two side components 200.

Since the drive gear 610 is fixedly connected to the pivot shaft 500, when the upper component 300 is rotated, the pivot shaft 500 can rotate along with the upper component 300, causing the drive gear 610 to rotate relative to the lower component 100 along with the pivot shaft 500. Both ends of the transmission shaft 620 are each provided with the driven gear 670. The driven gear 670 provided at the top end of the transmission shaft 620 is engaged with the drive gear 610, so that the drive gear 610 drives the driven gear 670 to rotate, thereby driving the transmission shaft 620 to rotate. The driven gear 670 provided at the bottom end of the transmission shaft 620 is engaged with the transmission rack 630, driving the transmission rack 630 to slide relative to the lower component 100, thereby driving the sliding block 640 to move relative to the lower component 100 via the transmission rack 630. Since the sliding block 640 is relatively fixed to the side component 200, during the moving of the sliding block 640 relative to the lower component 100, it can drive the side component 200 to move relative to the lower component 100. Thus, the upper component 300 can be drivingly connected to the side component 200.

Specifically, the transmission shaft 620 can be rotatably connected to a side of the insertion plug 310. In the embodiment, a protective sleeve 680 is provided on an exterior of the transmission shaft 620, and the transmission shaft 620 extends along the third direction Z. It should be understood that, in one embodiment, a long pivot shaft 500 can be provided in the upper component 300 to pivotally connect to the insertion plug 310. Alternatively, two short pivot shafts 500 spaced apart with each other can be provided to pivotally connect to the insertion plug 310. Regardless of the number of pivot shafts 500, each side of the insertion plug 310 along the second direction Y is provided with one transmission shaft 620. An end of the pivot shaft 500 corresponding to each transmission shaft 620 is provided with one drive gear 610. The drive gear 610 and the driven gear 670 are both bevel gears which can convert the vertical rotation direction of the pivot shaft 500 into the horizontal rotation direction of the transmission shaft 620. The transmission rack 630 is provided on the lower component 100 and can move along the first direction X. When the transmission rack 630 moves along the first direction X, the sliding block 640 is driven by the transmission rack 630 to move along the second direction Y. Each transmission shaft 620 corresponds to one side component 200, thereby driving the corresponding side component 200 to move relative to the lower component 100.

As shown in FIG. 5 to FIG. 8, specifically, the linkage assembly 600 further includes a guide drive block 650. The guide drive block 650 is fixedly connected to the transmission rack 630 and includes a guide slope 651. The guide slope 651 is inclined relative to the extending direction of the transmission rack 630. The sliding block 640 abuts against the guide slope 651. When the transmission rack 630 moves relative to the lower component 100 along the first direction X, the sliding block 640 is driven by the guide slope 651 to move along the second direction Y.

By providing the guide drive block 650 on the transmission rack 630 and providing the guide slope 651 on the guide drive block 650, when the transmission rack 630 moves along the first direction X, the sliding block 640 can move along the second direction Y under the force of the guide slope 651, thus enabling the transmission rack 630 to drive the sliding block 640 to move.

Specifically, when the transmission rack 630 is mounted in the housing of the lower component 100, the extending direction of the transmission rack 630 is the first direction X, and the angle between the guide slope 651 and the transmission rack 630 is an obtuse angle. The surface of the sliding block 640 that abuts against the guide slope 651 of the guide drive block 650 is configured as a inclined surface to increase the contact area between the sliding block 640 and the guide slope 651, thereby making the movement of the sliding block 640 more stable.

Furthermore, as shown in FIG. 8, a guide rail 120 is provided on the housing of the lower component 100. The guide rail 120 extends along the second direction Y. One side of the sliding block 640 is fixedly connected to the side component 200, and the other side of the sliding block 640 opposite to the side component 200 is slidably connected to the guide rail 120. Thus, when the transmission rack 630 moves along the first direction X, the sliding block 640 moves along the guide rail 120 in the second direction Y under the force of the guide slope 651.

As shown in FIG. 5 to FIG. 8, in an embodiment, when the sliding block 640 moves along the guide slope 651 until it abuts against the end of the guide drive block 650 away from the transmission rack 630, the distance between the two side components 200 is maximum. At this time, the side component 200 is no longer drivingly connected to the upper component 300. When the sliding block 640 moves to abut against the end face of the guide drive block 650 away from the transmission rack 630, even if the transmission rack 630 continues to move along the first direction X, the guide slope 651 of the guide drive block 650 no longer applies force to the sliding block 640, and thus the sliding block 640 no longer moves along the second direction Y. At this time, even if the upper component 300 continues to rotate, the side component 200 no longer moves relative to the lower component 100, which means the upper component 300 is not drivingly connected to the side component 200.

Specifically, the end face of the guide drive block 650 away from the transmission rack 630 is configured as a flat surface, which is parallel to the transmission rack 630. Correspondingly, the surface of the sliding block 640 that abuts against the end face of the guide drive block 650 away from the transmission rack 630 is configured as a flat surface, and the two flat surfaces fit with each other.

It should be understood that, in order to improve the stability of the movement of the side component 200, in the embodiment, at least two guide drive blocks 650 are provided, which are spaced apart along the extending direction of the transmission rack 630. Correspondingly, each guide drive block 650 corresponds to one sliding block 640.

As shown in FIG. 5 to FIG. 8, in an embodiment, the linkage assembly 600 further includes a sliding base 660. The sliding base 660 is fixedly connected to the sliding block 640. The side component 200 is detachably connected to the sliding base 660. A connector 920 is provided on the sliding base 660, and the connector 920 is electrically connected to the lower component 100. Specifically, the sliding base 660 is connected to the guide rail 120 provided on the lower component 100 via the sliding block 640, such that the sliding base 660 can move relative to the lower component 100. The sliding base 660 is detachably connected to the side component 200, so that the side component 200 can be detachably connected to the lower component 100. Furthermore, the connector 920 is provided on the sliding base 660, so that the lower component 100 can be electrically connected to the side component 200.

In an embodiment, the linkage assembly 600 further includes a first elastic element. An end of the first elastic element is connected to the sliding block 640, and the other end of the first elastic element abuts against the lower component 100. When the two side components 200 move away from each other, the first elastic element is compressed to provide an elastic force for the two side components 200 to move towards each other.

As shown in FIG. 5 to FIG. 8, in one embodiment, a cylindrical guide element is provided at an end of the sliding block 640 away from the transmission rack 630, and the first elastic element is located in the guide element. An end of the first elastic element abuts against the sliding block 640, and the other end of the first elastic element abuts against a positioning protrusion on the guide rail 120. When the sliding block 640 moves to the position furthest from the transmission rack 630, the first elastic element is compressed. The sliding block 640 abuts against the end of the guide drive block 650 away from the transmission rack 630. When the upper component 300 rotates in the opposite direction, i.e., becomes closed towards the lower component 100, the drive gear 610 is driven by the pivot shaft 500 to rotate, and the transmission rack 630 is driven by the driven gear 670 to move along the first direction X. Initially, due to a flat-surface contact between the sliding block 640 and the guide drive block 650, the transmission rack 630 and the sliding block 640 can only move relative to each other along the first direction X. At this time, the first elastic element applies a return force on the sliding block 640 towards the transmission rack 630. When the transmission rack 630 moves to the point where the slope of the sliding block 640 comes into contact with the guide slope 651 of the guide drive block 650, the sliding block 640 moves towards the transmission rack 630 under the return force of the first elastic element, thereby driving the side component 200 to move towards the transmission rack 630, so that the two side components 200 can be reset.

It should be understood that the number and the mounted position of the side components 200, and the fixed or detachable condition of the side components 200 relative to the lower component 100 can vary according to specific application scenarios.

For example, in an embodiment, two side components 200 can be provided, which includes a left component at the left end of the lower component 100 and a right component at the right end of the lower component 100. The left component is detachably connected to the lower component 100, and the right component is fixedly connected to the lower component 100. In another embodiment, the two side components 200 at both the left and right ends of the lower component 100 are detachably connected to the lower component 100. The upper component 300 can be drivingly connected to the two side components 200 simultaneously, and the two side components 200 can be locked relative to the lower component 100 after moving to a predetermined position. In other embodiments, only one side component 200 can be provided. This side component 200 is located at the left end of the lower component 100 and is detachably connected to the lower component 100. In yet other embodiments, one side component 200 can be provided, which is located at the right end of the lower component 100.

It should be noted that, under the driving of the upper component 300, when the distance between the two side components 200 is adjusted to the maximum, the two side components 200 can be locked relative to the lower component 100, so that the two side components 200 are no longer drivingly connected to the upper component 300. It can be understood that when the relative distance between the two side components 200 is adjusted to the maximum, the side components 200 can be locked to the lower component 100, at that time, the side components 200 no longer move relative to the lower component 100 when the upper component 300 is rotated. If the connection between the side components 200 and the upper component 300 needs to be re-established, the side components 200 and the lower component 100 should be unlocked.

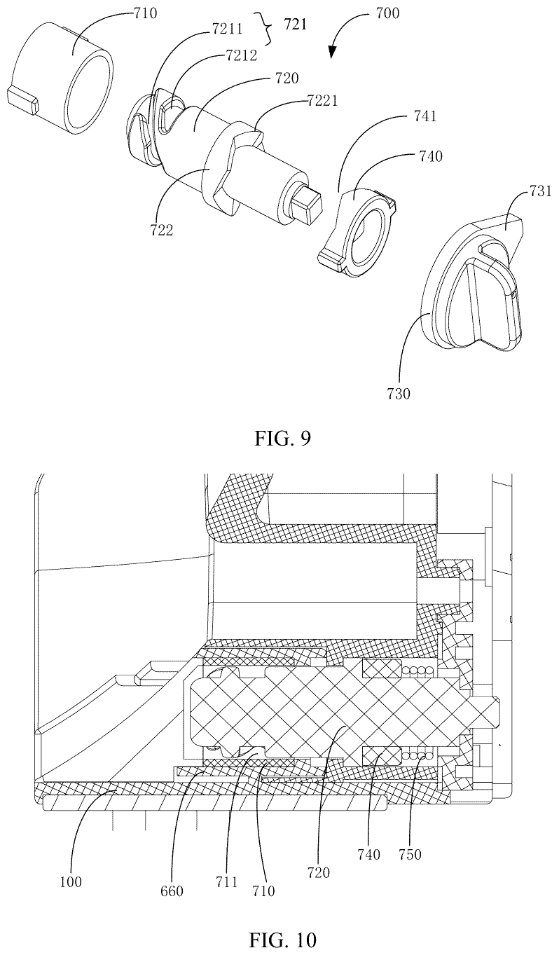

As shown in FIGS. 9 to 12, in an embodiment, the radio frequency coil assembly further includes a locking assembly 700. When the side component 200 moves to a predetermined position, the locking assembly 700 can lock the side component 200 relative to the lower component 100. The side component 200 is detachably connected to the lower component 100 via the locking assembly 700, thereby facilitating flexible mounting of the side component 200 according to different application scenarios. By using the locking assembly 700, when the side component 200 is adjusted to the predetermined position relative to the lower component 100, the locking assembly 700 can lock the side component 200, thereby improving the stability and reliability of the radio frequency coil assembly in different application scenarios.

Specifically, as shown in FIG. 9, the locking assembly 700 includes a sleeve 710, a locking element 720, and a position adjusting element 730. The sleeve 710 is fixedly connected to the lower component 100. The locking element 720 is rotatably connected to the side component 200, and the locking element 720 is detachably connected to the sleeve 710. The position adjusting element 730 is fixedly connected to the locking element 720. When the side component 200 moves to the predetermined position, a portion of the position adjusting element 730 can abut against an end of the lower component 100 to limit movement of the side component 200 relative to the lower component 100.

By fixedly connecting the sleeve 710 to the lower component 100, rotatably connecting the locking element 720 to the side component 200, and detachably connecting the locking element 720 to the sleeve 710, the side component 200 can be detachably connected to the lower component 100. When the side component 200 moves to the predetermined position, a portion of the position adjusting element 730 abuts against the end of the lower component 100 to prevent the side component 200 from further moving relative to the lower component 100, thereby maintaining the side component 200 at the predetermined position.

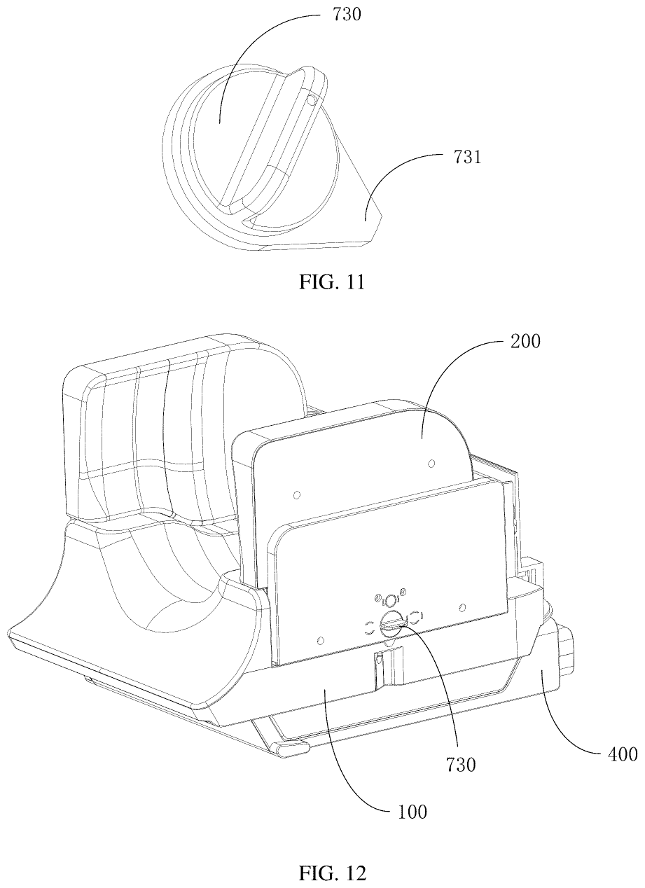

As shown in FIGS. 11 and 12, in an embodiment, a protrusion portion 731 is provided on the position adjusting element 730. When the distance between the two side components 200 is maximum, the position adjusting element 730 can be rotated to enable the protrusion portion 731 to abut against the lower component 100, thereby locking the side component 200 relative to the lower component 100.

By providing the protrusion portion 731 on the position adjusting element 730 and enabling the protrusion portion 731 and the lower component 100 to abut against each other, the position of the side component 200 relative to the lower component 100 can be secured.

Specifically, after the position adjusting element 730 is rotated to lock the side component 200 and the sliding base 660, if the distance between the left and right side components 200 is the maximum value, the position adjusting element 730 can be rotated to cause the protrusion portion 731 to abut against the lower component 100, thus forming a limit and thereby locking the side component 200 relative to the lower component 100. At this time, the left and right side components 200, the sliding base 660, and the sliding block 640 are in a fixedly connected state. The position adjusting element 730 can limit the sliding of the sliding block 640, so that the transmission rack 630 and the sliding block 640 are no longer in an linkage relationship. The rotating of the upper component 300 no longer affects the movements of the left and right side components 200, and the distance between the two side components 200 remains in the maximum value.

Since the locking element 720 is detachably connected to the sleeve 710, rotating the position adjusting element 730 can drive the locking element 720 to rotate relative to the sleeve 710, thereby fixing the locking element 720 to the sleeve 710.

Specifically, the sleeve 710 is fixedly connected to the sliding base 660. The locking element 720 is rotatably connected to the side component 200, and the locking element 720 and the sleeve 710 are connected to each other, so that the side component 200 is detachably connected to the sliding base 660. As such, the side component 200 can move relative to the lower component 100 and is detachably connected to the lower component 100. Fixedly connecting the position adjusting element 730 to the locking element 720 facilitates the user applying force to the locking element 720 via the position adjusting element 730, thereby achieving rotation of the locking element 720 relative to the side component 200.

Specifically, the side component 200 includes a side plate. The locking element 720 is rotatably connected to the side plate, and the position adjusting element 730 is located on an outer side of the side plate to facilitate the user to operate.

As shown in FIG. 9, in an embodiment, the outer peripheral surface of the end of the locking element 720 away from the position adjusting element 730 is provided with a limit groove 721. The inner peripheral surface of the sleeve 710 is provided with a limit protrusion 711 (see FIG. 10). The limit protrusion 711 can be engaged in the limit groove 721 to prevent the locking element 720 from disengaging from the sleeve 710.

By providing the limit groove 721 on the end of the locking element 720 and providing the limit protrusion 711 on the inner peripheral surface of the sleeve 710, the limit protrusion 711 and the limit groove 721 can cooperate to restrict the locking element 720 and the sleeve 710 relative to each other, thereby achieving a detachable connection between the side component 200 and the lower component 100.

As shown in FIG. 9, further, the limit groove 721 includes a helical segment 7211 and a transverse segment 7212 that are in communication with each other. The extending direction of the transverse groove segment 7212 is perpendicular to the axis of the locking element 720. The limit protrusion 711 can slide in the helical segment 7211 and enter the transverse segment 7212 from the helical segment 7211. When the limit protrusion 711 is engaged with the transverse segment 7212, the transverse segment 7212 and the limit protrusion 711 cooperate to prevent the locking element 720 from disengaging from the sleeve 710.

By dividing the limit groove 721 into the helical segment 7211 and transverse segment 7212, and configuring the limit protrusion 711 to match the shape of the limit groove 721, the locking element 720 can be rotated, such that the helical segment 7211 on the locking element 720 is screwed tight with the limit protrusion 711 on the sleeve 710 along the helical direction thereof. When the limit protrusion 711 enters the transverse segment 7212 of the limit groove 721, mutual limiting is formed between the limit protrusion 711 and the inner wall of the transverse segment 7212, thereby preventing the locking element 720 from disengaging from the sleeve 710 along its axial direction. This structural configuration is simple and facilitates installation and disassembly.

It should be understood that, in the embodiment, the rotation angle of the helical segment 7211 on the locking element 720 is 90 degrees. That is, when mounting the side component 200 on the lower component 100, the position adjusting element 730 is rotated by 90 degrees to enable the locking element 720 to be connected to the sleeve 710.

As shown in FIG. 9, in an embodiment, the outer peripheral surface of the locking element 720 is further provided with an anti-rotation protrusion block 722, and the anti-rotation protrusion block 722 is provided between the limit groove 721 and the position adjusting element 730. The anti-rotation protrusion block 722 is arranged in a circle along the circumferential direction of the locking element 720. An end face of the anti-rotation protrusion block 722 towards the position adjusting element 730 is provided with a tooth-like anti-rotation protrusion 7221. The locking assembly 700 further includes an anti-rotation pressure block 740, and the anti-rotation pressure block 740 is movably connected to the side component 200 and is movably sleeved on the locking element 720. An end face of the anti-rotation pressure block 740 towards the anti-rotation protrusion 7221 is provided with an anti-rotation recess 741. The anti-rotation protrusion 7221 and the anti-rotation recess 741 cooperate with each other to restrict the rotation of the locking element 720.

By providing the anti-rotation protrusion block 722 on the outer peripheral surface of the locking element 720, and providing the anti-rotation protrusions 7221 on the end face of the anti-rotation protrusion block 722 towards the position adjusting element 730, when the anti-rotation pressure block 740 is movably connected to the side component 200 and sleeved on the locking element 720, the anti-rotation pressure block 740 can move relative to the locking element 720. The anti-rotation recess 741 is provided on the anti-rotation pressure block 740, so that the anti-rotation protrusion protrusions 7221 can be engaged with the anti-rotation recess 741 to lock the rotation of the locking element 720.

It should be understood that the anti-rotation pressure block 740 can only move linearly relative to the side component 200 and cannot rotate relative to the side component 200. Specifically, the anti-rotation pressure block 740 is substantially annular. Two limiting blocks are provided on the outer peripheral surface of the anti-rotation pressure block 740, and the two limiting blocks are arranged opposite each other along the radial direction of the anti-rotation pressure block 740. Two guide grooves are provided on the side plate of the side component 200. The two limit blocks are movably received in the two guide grooves, so that the anti-rotation pressure block 740 can only move along the extending direction of the guide grooves.

As shown in FIG. 10, in an embodiment, the locking assembly 700 further includes a second elastic element 750, and the second elastic element 750 is sleeved on the locking element 720. Both ends of the second elastic element 750 abut against the anti-rotation pressure block 740 and the position adjusting element 730, respectively. The second elastic element 750 provides preload for the cooperation between the anti-rotation pressure block 740 and the anti-rotation protrusion block 722.

Specifically, the second elastic element 750 is a spring. The second elastic element 750 is sleeved on the locking element 720. The end of the locking element 720 that cooperates with the position adjusting element 730 is provided with a square pin. The position adjusting element 730 is provided with a square mounting slot. The square pin can be inserted and fixed into the square mounting slot.

When the locking element 720 is to be rotated, the position adjusting element 730 can be firstly pulled outward along the axial direction of the locking element 720. At this time, the anti-rotation pressure block 740 moves along with the position adjusting element 730 in a direction away from the anti-rotation protrusion block 722, causing the anti-rotation recess 741 on the anti-rotation pressure block 740 to move in a direction away from the anti-rotation protrusion 7221 of the anti-rotation protrusion block 722. Then, the position adjusting element 730 can be rotated, and the locking element 720 is driven by the position adjusting element 730 to rotate relative to the side component 200. When the locking element 720 is rotated to the predetermined position, the position adjusting element 730 can be pushed towards the anti-rotation protrusion block 722. The anti-rotation pressure block 740 moves towards the anti-rotation protrusion block 722, causing the anti-rotation recess 741 of the anti-rotation pressure block 740 to be engaged with the anti-rotation protrusion 7221 of the anti-rotation protrusion block 722. At this time, the second elastic element 750 is in a compressed state. The anti-rotation pressure block 740, under the elastic force of the second elastic element 750, maintains cooperation with the anti-rotation protrusion block 722, thereby ensuring that the locking element 720 cannot rotate relative to the side component 200.

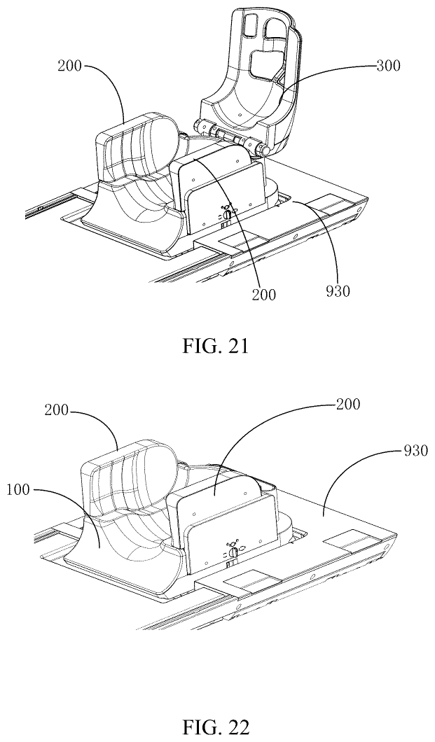

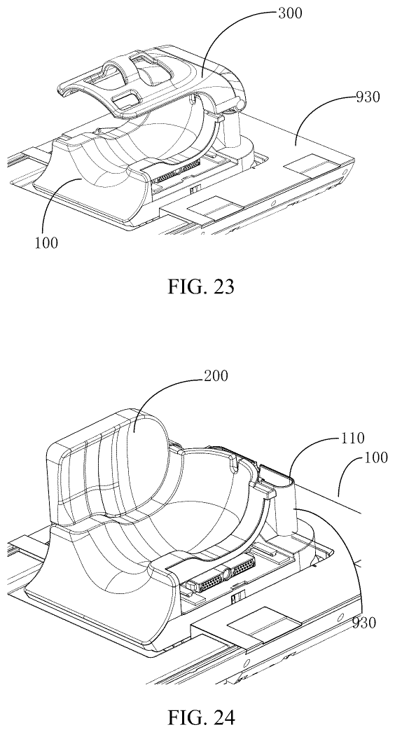

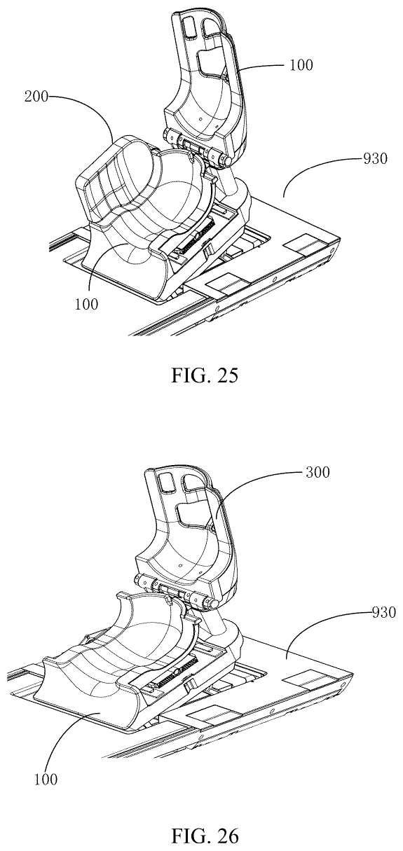

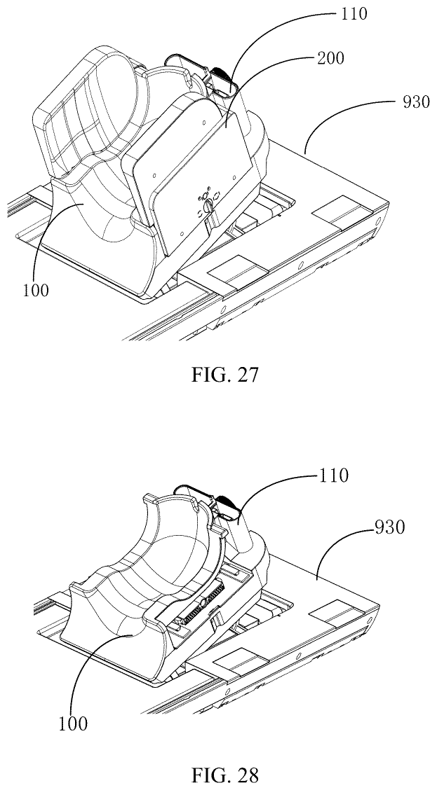

As shown in FIGS. 20 to 28, an embodiment of the present disclosure further provides a magnetic resonance imaging system, including a patient couch 930 and the radio frequency coil assembly according to any of the aforementioned embodiment. The radio frequency coil assembly is placed on the surface of the patient couch 930. The radio frequency coil assembly includes a lower component 100, two side components 200, and an upper component 300. The two side components 200 include a left component and a right component detachably provided at opposite ends of the lower component 100, respectively. The upper component 300 is rotatably connected to the lower component 100 and is drivingly connected to at least one side component 200. The lower component 100, the two side components 200, and the upper component 300 cooperatively define an accommodating cavity 910 with an opening. The lower component 100, the side components 200, and the upper component 300 are each provided with a coil unit 950. When the upper component 300 rotates relative to the lower component 100, the two side components 200 are driven by the upper component 300 and move laterally relative to the lower component 100 from an open position to a plurality of closed positions, so as to adjust the volume size of the accommodating cavity 910 to adapt to patients 940 with different head sizes.

The radio frequency coil assembly as described above is arranged on the patient couch 930, so that when performing scanning examinations on corresponding regions of the patient 940 laid on the patient couch 930, the patient 940 can lie supine or on their side on the patient couch 930. The upper component 300 is configured to be drivingly connected to at least one side component 200, so that when the upper component 300 is rotated relative to the lower component 100, the side component 200 can be driven by the upper component 300 to move relative to the lower component 100, thereby adjusting the volume size of the accommodating cavity 910. This structural configuration makes the volume size of the accommodating cavity 910 adjustable, enabling the radio frequency coil assembly to be better attached to the patient's head and neck by adjusting the volume size of the accommodating cavity 910, thereby improving the signal-to-noise ratio of the radio frequency coil assembly.

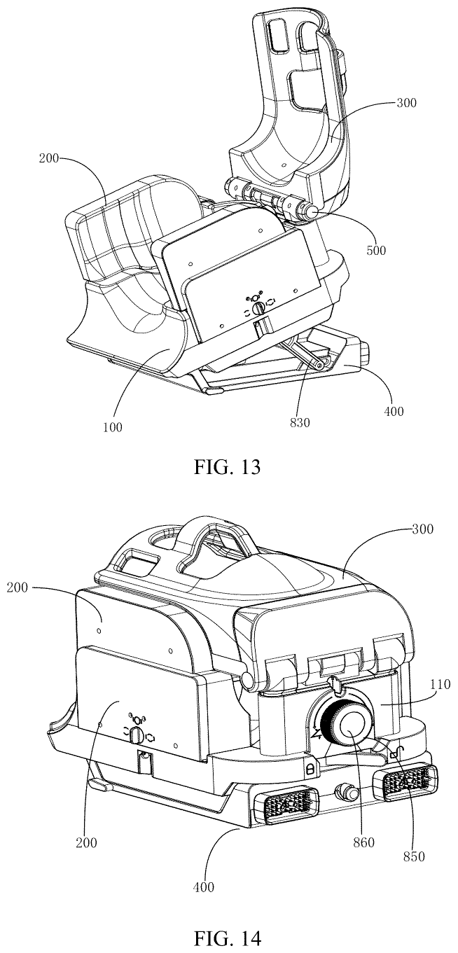

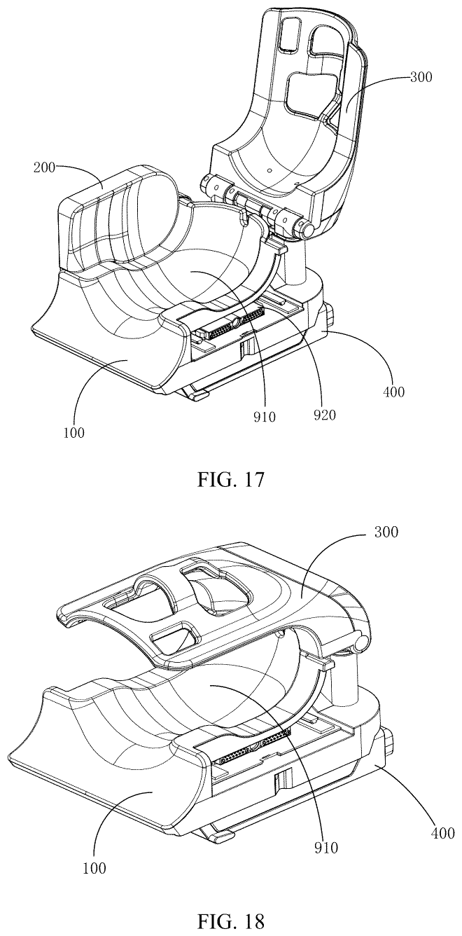

As shown in FIGS. 13 to 19, in an embodiment, the radio frequency coil assembly further includes a base 400 and a tilt device 800. When the radio frequency coil assembly is provided on the patient couch 930, the base 400 is detachably connected to the patient couch 930. The lower component 100 is connected to the base 400 via the tilt device 800, so that an angle between the lower component 100 and the base 400 is adjustable.

Since the lower component 100 is connected to the base 400 via the tilt device 800, the angle between the lower component 100 and the base 400 can be adjustable. Since the base 400 is connected to the patient couch 930, when adjusting the angle of the lower component 100 relative to the base 400, an inclination angle of the entire radio frequency coil assembly relative to the patient couch 930 can be adjusted accordingly, allowing the entire radio frequency coil assembly to be suitable for different patients 940.

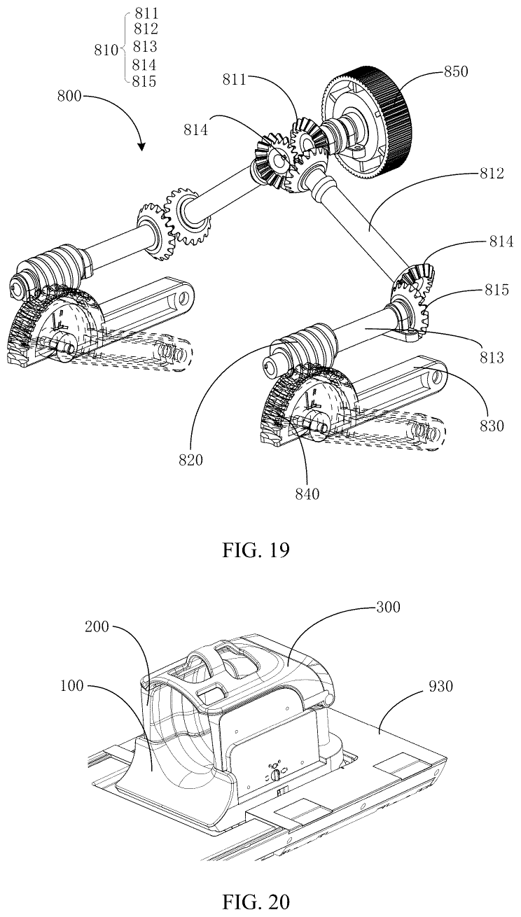

As shown in FIG. 19, in an embodiment, the tilt device 800 includes a gear assembly 810, a worm shaft 820, a connecting rod 830, a worm wheel 840, and a handle 850. The gear assembly 810 is connected to the lower component 100. The worm shaft 820 is drivingly connected to the gear assembly 810. One end of the connecting rod 830 is hinged to the base 400, and the other end of the connecting rod 830 is fixedly connected to the worm wheel 840. The worm wheel 840 is drivingly connected to the worm shaft 820. When the gear assembly 810 drives the worm shaft 820 to rotate, the worm shaft 820 drives the worm wheel 840 to rotate, and the connecting rod 830 rotates relative to the base 400 under the action of the worm wheel 840.

The gear assembly 810 drives the worm shaft 820 to rotate relative to the lower component 100, thus enabling the worm shaft 820 to drive the worm wheel 840 to rotate. The rotation of the worm wheel 840 drives the connecting rod 830 to rotate relative to the base 400, thereby enabling the lower component 100 to be lifted relative to the base 400.

As shown in FIG. 19, specifically, the gear assembly 810 includes a first bevel gear 811, a first transmission rod 812, and a second transmission rod 813. The first bevel gear 811 is rotatably connected to the lower component 100. Both ends of the first transmission rod 812 are connected to two second bevel gears 814, respectively. One second bevel gear 814 is engaged with the first bevel gear 811. An end of the second transmission rod 813 is connected to a third bevel gear 815, and the other end of the second transmission rod 813 is connected to the worm shaft 820. The third bevel gear 815 is engaged with the other second bevel gear 814.

Specifically, the first bevel gear 811 is rotatably connected to the insertion portion 110 of the lower component 100 via a rotating shaft. One end of the rotating shaft away from the first bevel gear 811 is fixed to the handle 850, thus the first bevel gear 811 can be driven to rotate by rotating the handle 850. The two first transmission rods 812 extend obliquely towards the two ends of the lower component 100. The two second bevel gears 814 at the ends of the first transmission rod 812 are engaged with the first bevel gear 811 and the third bevel gear 815 on the second transmission rod 813, respectively, thereby enabling the rotation of the worm shaft 820 by rotating the handle 850. It should be understood that in the embodiment, the extending directions of the worm shaft 820 and the second transmission rod 813 are along the first direction X. Thus, the gear assembly 810 drives the worm shaft 820 to rotate, the worm shaft 820 drives the worm wheel 840 to rotate, and the worm wheel 840 drives the connecting rod 830 to rotate relative to the base 400, thereby lifting the lower component 100. Since the worm wheel 840 and the worm shaft 820 inherently have a self-locking function, the lower component 100 can be fixed at any position within the design angle range.

By adjusting the angle of the radio frequency coil assembly relative to the patient couch 930 through the tilt device 800, stepless adjustment of the radio frequency coil assembly relative to the patient couch 930 can be achieved, thereby improving the operational flexibility of the radio frequency coil assembly.

It should be noted that, as shown in FIG. 5, to improve the compactness of the radio frequency coil assembly, in an embodiment, the pressing assembly 860 is provided in the handle 850. Specifically, the handle 850 is provided with a mounting hole concentric with the outer peripheral surface of the handle 850, and the pressing assembly 860 is movably provided within the mounting hole. The handle 850 is capable of rotating relative to the pressing assembly 860, and the pressing assembly 860 is movable along the axial direction of the handle 850, thereby enabling pressing of the pressing assembly 860. When the handle 850 is rotated, the operation of the tilt device 800 can be controlled through the handle 850, thereby achieving angle adjustment between the radio frequency coil assembly and the patient couch 930. Pressing the pressing assembly 860 can achieve locking or unlocking of the insertion connection between the upper component 300 and the lower component 100.

It should be understood that the radio frequency coil assembly provided in the aforementioned embodiments allows for the selective individual removal of the upper component 300 and the side component 200 according to different positioning requirements. Moreover, configuring the upper component 300 and the side component 200 to be detachably connected to the lower component 100 has the advantages such as convenient maintenance and cleaning.

As shown in FIGS. 20 to 28, after the radio frequency coil assembly is mounted on the patient couch 930, certain coil units can be removed according to different needs, and the inclination angle of the radio frequency coil assembly relative to the patient couch 930 can be adjusted to serve special people. The upper component 300 and the side component 200 are each provided with the connector 920 and an open-close lock structure at the detachment position thereof, providing a good user experience. The inclination angle of the radio frequency coil assembly is adjusted using a rotational form, allowing stepless adjustment and positioning at any angle between 0 and 25 degrees, thereby offering better adaptability.

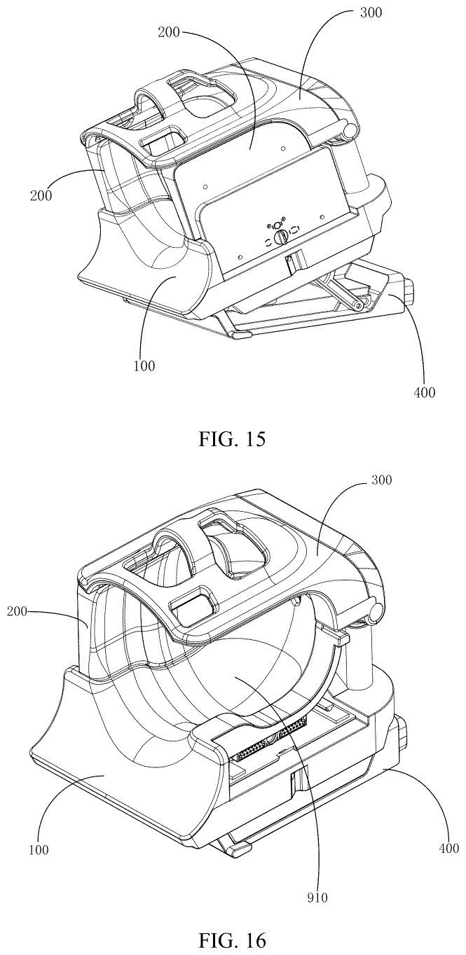

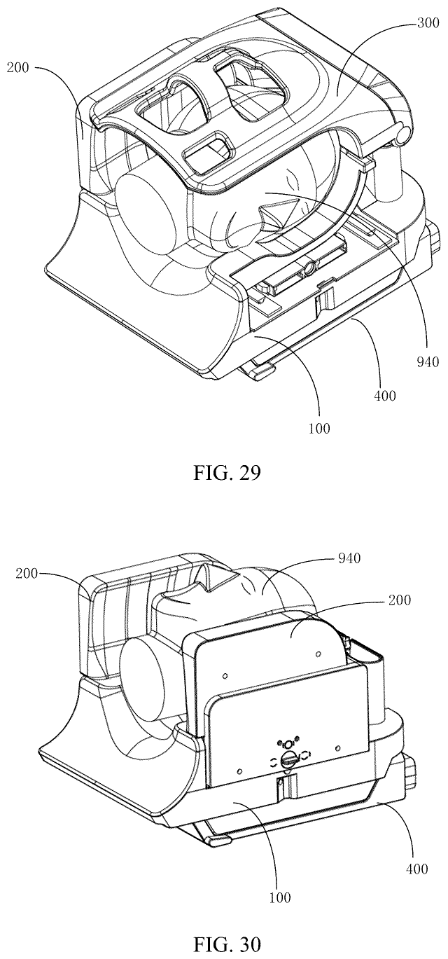

Specifically, for different usage scenarios, in some embodiments, as shown in FIG. 15, one side component 200 can be mounted on each of the left and right sides of the lower component 100, and the upper component 300 can be mounted on the upper part of the lower component 100. The two side components 200 can be drivingly connected to the upper component 300, simultaneously. Alternatively, one side component 200 can be drivingly connected to the upper component 300, while the other side component 200 remains fixed relative to the lower component 100. As shown in FIGS. 16, 17, and 29, only one side component 200 is mounted on the left side of the lower component 100, with the upper component 300 mounted on the top. The upper component 300 is drivingly connected to the left side component 200, this usage scenario is suitable for lateral decubitus scanning. Alternatively, as shown in FIG. 18, only the upper component 300 is mounted on the lower component 100, and the upper component 300 is capable of rotating relative to the lower component 100. It should be understood that when the radio frequency coil assembly is mounted on the patient couch 930, the usage state is still suitable. For example, as shown in FIGS. 22 and 30, the side components 200 can be provided on the left and right sides of the lower component 100, and the upper component 300 can be omitted. This usage scenario is suitable for supine scanning. Alternatively, as shown in FIG. 24, a side component 200 can be provided only on the left side of the lower component 100, and no components are provided on the right side and the top side of the lower component 100.

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the present application.

The above-described embodiments are only several implementations of the present application, and the descriptions are relatively specific and detailed, but they should not be construed as limiting the scope of the present application. It should be understood by those of ordinary skill in the art that various modifications and improvements can be made without departing from the concept of the present application, and all fall within the protection scope of the present application. Therefore, the patent protection of the present application shall be defined by the appended claims.

What is claimed is:

1. A radio frequency coil assembly for a magnetic resonance imaging system, comprising:
a lower component;
two side components detachably connected to opposite ends of the lower component, respectively; and
an upper component rotatably connected to the lower component and drivingly connected to at least one side component;
wherein the lower component, the two side components, and the upper component are each provided with a coil unit therein, and the lower component, the two side components, and the upper component cooperatively define an accommodating cavity with an opening;
wherein when the upper component is rotated relative to the lower component, the at least one side component is driven by the upper component to move relative to the lower component, so as to adjust a volume size of the accommodating cavity.

2. The radio frequency coil assembly according to claim 1, wherein the upper component comprises an insertion plug, the lower component comprises an insertion portion, the insertion plug and the insertion portion are each provided with a connector, and the insertion plug is inserted into the insertion portion and electrically connected to the insertion portion via the connector.

3. The radio frequency coil assembly according to claim 1, further comprising:
a pivot shaft connected to the upper component and capable of rotating relative to the lower component; and
a linkage assembly, wherein the side component is connected to the pivot shaft via the linkage assembly, so as to convert rotational motion of the upper component into translational motion of the two side components.

4. The radio frequency coil assembly according to claim 3, wherein the linkage assembly comprises:
a drive gear fixedly connected to the pivot shaft;
a transmission shaft rotatably connected to the lower component, wherein two driven gears are provided at both ends of the transmission shaft, respectively;
a transmission rack movably connected to the lower component, wherein one driven gear is engaged with the drive gear, and another driven gear is engaged with the transmission rack; and
a sliding block fixedly connected to the side component, wherein the sliding block is drivingly connected to the transmission rack to drive the side component to move relative to the lower component, thereby increasing a distance between the two side components.

5. The radio frequency coil assembly according to claim 4, wherein the linkage assembly further comprises:
a guide drive block fixedly connected to the transmission rack and comprising a guide slope, wherein the guide slope is inclined relative to an extending direction of the transmission rack;
wherein the sliding block abuts against the guide slope, when the transmission rack moves relative to the lower component in a first direction, the sliding block is driven by the guide slope to move in a second direction, and the first direction intersects the second direction.

6. The radio frequency coil assembly according to claim 5, wherein the lower component is provided with a guide rail extending in the second direction, one side of the sliding block is fixedly connected to the side component, and another side of the sliding block is slidably connected to the guide rail; when the transmission rack moves in the first direction, the sliding block moves along the guide rail under a force of the guide slope.

7. The radio frequency coil assembly according to claim 5, wherein an end surface of the guide drive block away from the transmission rack is a flat surface parallel to the transmission rack, and a surface of the sliding block abutting against the end surface of the guide drive block away from the transmission rack is also a flat surface.

8. The radio frequency coil assembly according to claim 4, wherein the linkage assembly further comprises:
a sliding base fixedly connected to the sliding block,
wherein the side component is detachably connected to the sliding base, and the sliding base is provided with a connector electrically connected to the lower component.

9. The radio frequency coil assembly according to claim 4, wherein the linkage assembly further comprises a first elastic member,
wherein one end of the first elastic member abuts against the sliding block, and another end of the first elastic member abuts against the lower component;
wherein when the two side components move away from each other, the first elastic member is compressed and is configured to provide force for the two side components to move toward each other.

10. The radio frequency coil assembly according to claim 9, wherein an end of the sliding block away from the transmission rack is provided with a guide element, the lower component is provided with a guide rail extending in the second direction, and the first elastic member is provided within the guide element and abuts against a positioning protrusion on the guide rail.

11. The radio frequency coil assembly according to claim 1, further comprising a locking assembly,
wherein the two side components are detachably connected to the lower component via the locking assembly, and when the side components move to a predetermined position, the locking assembly is capable of locking the two side components relative to the lower component.

12. The radio frequency coil assembly according to claim 11, wherein the locking assembly comprises:
a sleeve fixedly connected to the lower component;
a locking element rotatably connected to the side component, wherein the locking element is inserted into the sleeve; and
a position adjusting element fixedly connected to the locking element;
wherein the position adjusting element is capable of driving the locking element to rotate relative to the sleeve, thereby fixing the locking element to the sleeve.

13. The radio frequency coil assembly according to claim 1, further comprising a base and a tilt device,
wherein the lower component is connected to the base via the tilt device, and the tilt device is configured to adjust an angle between the lower component and the base.

14. A radio frequency coil assembly, comprising:
a lower component, an upper component, a left component, and a right component;
wherein the lower component, the upper component, the left component, and the right component are each provided with a coil unit therein;
wherein the upper component is rotatably connected to the lower component and is drivingly connected to the left component and the right component;
when the upper component rotates relative to the lower component from an open position to a closed position, the left component and the right component are driven by the upper component to move relative to the lower component toward a patient, thereby wrapping sides of a head of the patient.

15. The radio frequency coil assembly according to claim 14, wherein the left component and the right component are driven by the upper component to move relative to the lower component from an open position to a plurality of closed positions to adapt to patients with different head sizes.

16. The radio frequency coil assembly according to claim 15, wherein the left component and the right component rotate relative to the lower component along a longitudinal axis, or the left component and the right component translate horizontally relative to the lower component.

17. A magnetic resonance imaging system, comprising:
a patient couch; and
a radio frequency coil assembly provided on a surface of the patient couch, the radio frequency coil assembly comprising a lower component, an upper component, and at least one side component;
wherein the lower component, the upper component, and the at least one side component are each provided with a coil unit therein;
wherein the upper component is rotatably connected to the lower component and is drivingly connected to the at least one side component;
when the upper component rotates relative to the lower component from an open position to a closed position, the at least one side component is driven by the upper component to move relative to the lower component horizontally from an open position to a plurality of closed positions to adapt to patients with different head sizes.

18. The magnetic resonance imaging system according to claim 17, wherein when the upper component rotates relative to the lower component from the closed position to the open position, the at least one side component is driven by the upper component to move relative to the lower component horizontally from the closed position to the open position.

19. The magnetic resonance imaging system according to claim 17, wherein sides of the lower component, the upper component, and the at least one side component towards the patients are matched with contours heads of the patients.

20. The magnetic resonance imaging system according to claim 17, wherein the radio frequency coil assembly further comprises a base and a tilt device, the lower component is connected to the base through the tilt device, the base is connected to the patient couch, and the tilt device is configured to adjust an inclination angle of the radio frequency coil assembly relative to the patient couch.
